(19) United States
(12) Patent Application Publication
(10) Pub. No.: US 2026/0269844 A1
(43) Pub. Date: Sep. 10, 2026

(54) LDPC LOW CODING RATE DESIGNS FOR NEXT-GENERATION WLAN

(71) Applicant: MEDIATEK INC., Hsinchu City (TW)

(72) Inventors: Shengquan HU, San Jose, CA (US); Jianhan LIU, San Jose, CA (US); Thomas Edward PARE, Jr., San Jose, CA (US)

(21) Appl. No.: 18/873,538

(22) PCT Filed: Jun. 16, 2023
(86) PCT No.: PCT/CN2023/100637

§ 371 Date: Dec. 10, 2024

Related U.S. Application Data
(60) Provisional application No. 63/353,089, filed on Jun. 17, 2022.

(51) Int. Cl. H03M 13/11; H03M 13/00; H04L 1/00

(52) U.S. Cl. CPC H03M 13/1102; H03M 13/618; H03M 13/6356; H03M 13/6362; H04L 1/003

(57) ABSTRACT

Techniques pertaining to low-density parity-check (LDPC) low coding rate designs for next-generation wireless local area networks (WLANs) are described. A processor of an apparatus (e.g., station (STA)) receives a plurality of input bits and codes the plurality of input bits. In coding the input bits, the processor encodes the input bits by a LDPC encoder of the processor using a base code rate. The processor also performs either or both of a repeating operation and a shortening operation on an output of the LDPC encoder to result in an effective coding rate of coding the input bits that is lower than the base code rate.

### CROSS REFERENCE TO RELATED PATENT APPLICATION

The present disclosure is part of a non-provisional patent application claiming the priority benefit of U.S. Provisional Patent Application Nos. 63/353,089, filed 17 Jun. 2022, the content of which herein being incorporated by reference in its entirety.

### TECHNICAL FIELD

The present disclosure is generally related to wireless communications and, more particularly, to low-density parity-check (LDPC) low coding rate designs for next-generation wireless local area networks (WLANs).

### BACKGROUND

Unless otherwise indicated herein, approaches described in this section are not prior art to the claims listed below and are not admitted as prior art by inclusion in this section.

With respect to wireless communications, such as in accordance with the Institute of Electrical and Electronics Engineers (IEEE) 802.11 standards, high reliability and coverage range enhancement are considered as key features for next-generation Wi-Fi. However, at the present time, designs of how to utilize LDPC low coding rates in next-generation WLANs remains to be defined or otherwise specified. Therefore, there is a need for a solution of LDPC low coding rate designs for next-generation WLANs.

### SUMMARY

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

An objective of the present disclosure is to provide schemes, concepts, designs, techniques, methods and apparatuses pertaining to LDPC low coding rate designs for next-generation WLANs. Moreover, new robust designs of modulation and coding scheme (MCS) with low coding rate LDPC are also proposed under the various proposed schemes.

In one aspect, a method may involve receiving a plurality of input bits. The method may also involve coding the plurality of input bits by: (i) encoding the input bits by a LDPC encoder of the processor using a base code rate; and (ii) performing either or both of a repeating operation and a shortening operation on an output of the LDPC encoder to result in an effective coding rate of coding the input bits that is lower than the base code rate.

In another aspect, an apparatus may include a transceiver configured to communicate wirelessly and a processor coupled to the transceiver. The processor may receive a plurality of input bits. The processor may also code the plurality of input bits by: (i) encoding the input bits by a LDPC encoder of the processor using a base code rate; and (ii) performing either or both of a repeating operation and a shortening operation on an output of the LDPC encoder to result in an effective coding rate of coding the input bits that is lower than the base code rate.

It is noteworthy that, although description provided herein may be in the context of certain radio access technologies, networks and network topologies such as, Wi-Fi, the proposed concepts, schemes and any variation(s)/derivative(s) thereof may be implemented in, for and by other types of radio access technologies, networks and network topologies such as, for example and without limitation, Bluetooth, ZigBee, 5^{th} Generation (5G)/New Radio (NR), Long-Term Evolution (LTE), LTE-Advanced, LTE-Advanced Pro, Internet-of-Things (IoT), Industrial IoT (IIoT) and narrowband IoT (NB-IoT). Thus, the scope of the present disclosure is not limited to the examples described herein.

### BRIEF DESCRIPTION OF THE DRAWINGS

The accompanying drawings are included to provide a further understanding of the disclosure and are incorporated in and constitute a part of the present disclosure. The drawings illustrate implementations of the disclosure and, together with the description, serve to explain the principles of the disclosure. It is appreciable that the drawings are not necessarily in scale as some components may be shown to be out of proportion than the size in actual implementation to clearly illustrate the concept of the present disclosure.

FIG. 1 is a diagram of an example network environment in which various solutions and schemes in accordance with the present disclosure may be implemented.

FIG. 2 is a diagram of an example design under a proposed scheme in accordance with the present disclosure.

FIG. 3 is a diagram of an example design under a proposed scheme in accordance with the present disclosure.

FIG. 4 is a diagram of an example design under a proposed scheme in accordance with the present disclosure.

FIG. 5 is a diagram of an example design under a proposed scheme in accordance with the present disclosure.

FIG. 6 is a diagram of an example design under a proposed scheme in accordance with the present disclosure.

FIG. 7 is a diagram of an example design under a proposed scheme in accordance with the present disclosure.

FIG. 8 is a diagram of an example design under a proposed scheme in accordance with the present disclosure.

FIG. 9 is a diagram of an example scenario under a proposed scheme in accordance with the present disclosure.

FIG. 10 is a diagram of an example scenario under a proposed scheme in accordance with the present disclosure.

FIG. 11 is a diagram of an example scenario under a proposed scheme in accordance with the present disclosure.

FIG. 12 is a diagram of an example scenario under a proposed scheme in accordance with the present disclosure.

FIG. 13 is a diagram of an example scenario under a proposed scheme in accordance with the present disclosure.

FIG. 14 is a diagram of an example scenario under a proposed scheme in accordance with the present disclosure.

FIG. 15 is a diagram of an example design under a proposed scheme in accordance with the present disclosure.

FIG. 16 is a diagram of an example design under a proposed scheme in accordance with the present disclosure.

FIG. 17 is a block diagram of an example communication system in accordance with an implementation of the present disclosure.

FIG. 18 is a flowchart of an example process in accordance with an implementation of the present disclosure.

### DETAILED DESCRIPTION OF PREFERRED EMBODIMENTS

Detailed embodiments and implementations of the claimed subject matters are disclosed herein. However, it shall be understood that the disclosed embodiments and implementations are merely illustrative of the claimed subject matters which may be embodied in various forms. The present disclosure may, however, be embodied in many different forms and should not be construed as limited to the exemplary embodiments and implementations set forth herein. Rather, these exemplary embodiments and implementations are provided so that description of the present disclosure is thorough and complete and will fully convey the scope of the present disclosure to those skilled in the art. In the description below, details of well-known features and techniques may be omitted to avoid unnecessarily obscuring the presented embodiments and implementations.

### Overview

Implementations in accordance with the present disclosure relate to various techniques, methods, schemes and/or solutions pertaining to LDPC low coding rate designs for next-generation WLANs. According to the present disclosure, a number of possible solutions may be implemented separately or jointly. That is, although these possible solutions may be described below separately, two or more of these possible solutions may be implemented in one combination or another.

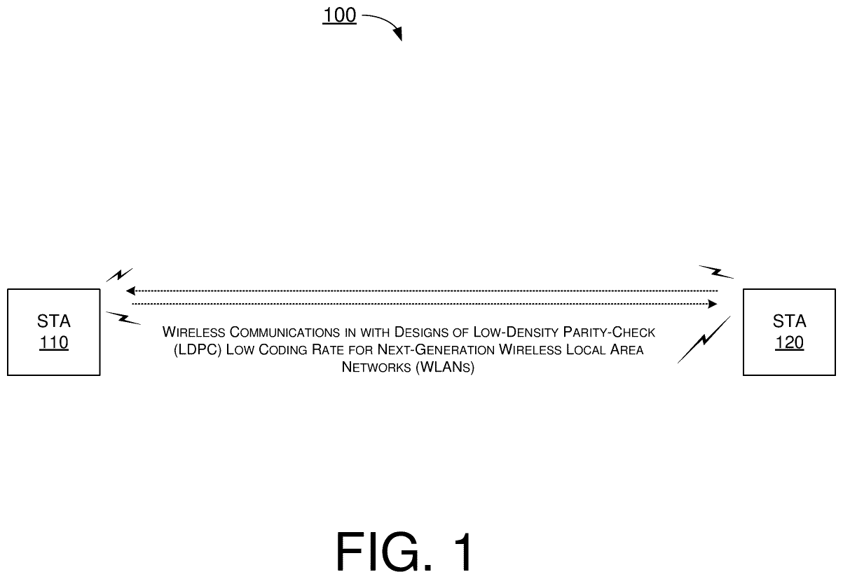

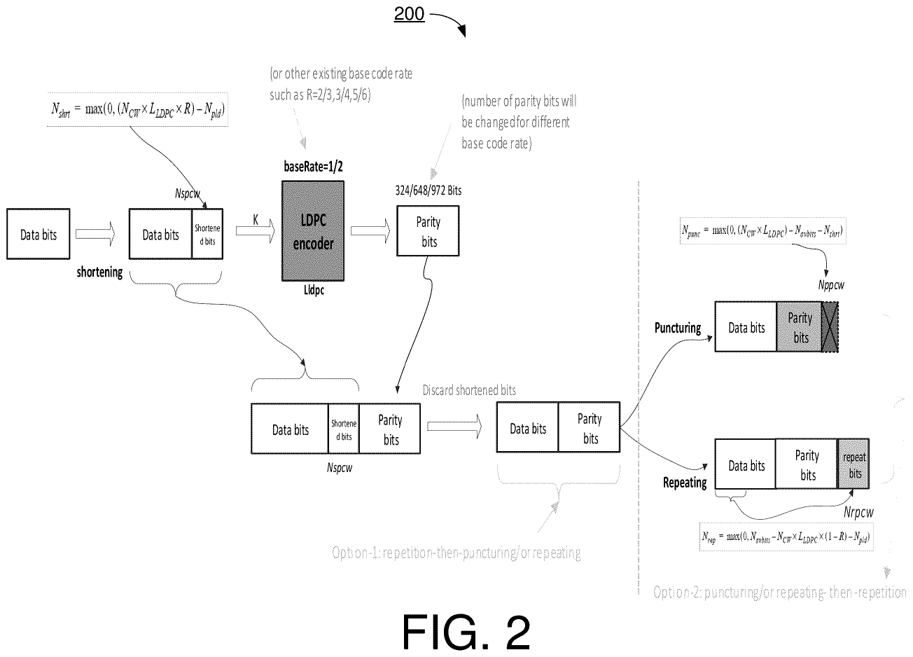

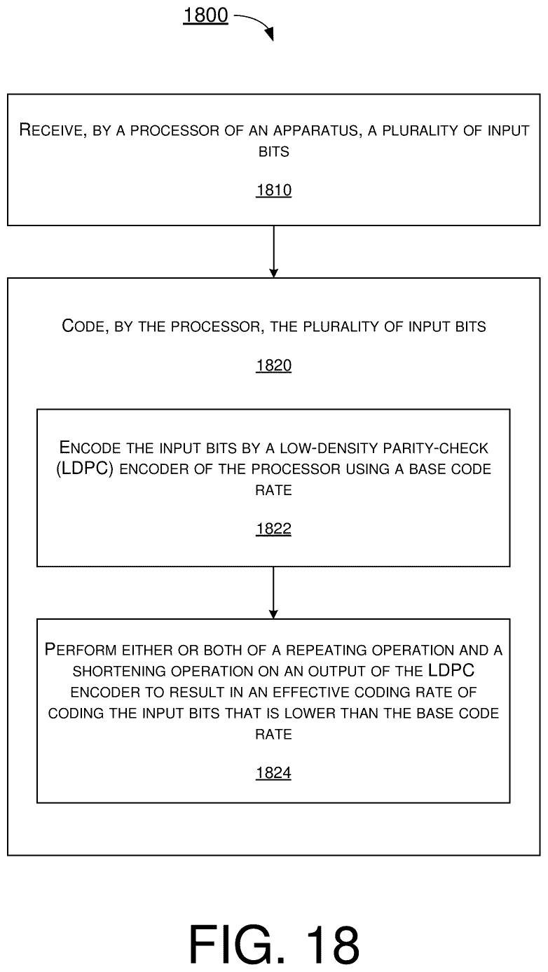

FIG. 1 illustrates an example network environment 100 in which various solutions and schemes in accordance with the present disclosure may be implemented. FIG. 2~FIG. 18 illustrate examples of implementation of various proposed schemes in network environment 100 in accordance with the present disclosure. The following description of various proposed schemes is provided with reference to FIG. 1~FIG. 18.

Referring to FIG. 1, network environment 100 may involve at least a station (STA) 110 communicating wirelessly with a STA 120. Either of STA 110 and STA 120 may be an access point (AP) STA or, alternatively, either of STA 110 and STA 120 may function as a non-AP STA. In some cases, STA 110 and STA 120 may be associated with a basic service set (BSS) in accordance with one or more IEEE 802.11 standards (e.g., IEEE 802.11be and future-developed standards). Each of STA 110 and STA 120 may be configured to communicate with each other by utilizing the LDPC low coding rate designs for next-generation WLANs in accordance with various proposed schemes described below. That is, either or both of STA 110 and STA 120 may function as a “user” in the proposed schemes and examples described below. It is noteworthy that, while the various proposed schemes may be individually or separately described below, in actual implementations some or all of the proposed schemes may be utilized or otherwise implemented jointly. Of course, each of the proposed schemes may be utilized or otherwise implemented individually or separately.

Under various proposed schemes in accordance with the present disclosure, there may be different LDPC low coding rate design options or approaches. In a first option or approach (Approach-1), a plurality of input bits may be coded by either a repeat-then-puncture operation or a puncture-then-repeat operation. Moreover, in Approach-1, a coding rate R of ½ may be used as the base coding rate to achieve an effective low coding rate by N times (Nx) of repetitions, Nx=2, 3, 4, 6, 8 or 16 corresponding to the effective coding rate (eR)=¼, ⅙, ⅛, 1/12, 1/16, 1/24 or 1/32. In a second option or approach (Approach-2), R=½ may be used as the base coding rate to achieve a low effective coding rate eR=⅓, ¼, ⅙ or ⅛ by a “default shortening” operation. In a third operation or approach (Approach-3), the above-described Approach-1 and Approach-2 may be combined by: (1) using different low coding rates such as R=½, ⅓, ¼, ⅙ or ⅛ as the base coding rate and (2) further performing repetition. Thus, Approach-3 may achieve an even lower effective coding rate of eR=¼, ⅙, ⅛, 1/12, 1/16, 1/24 or 1/32.

FIG. 2 illustrates an example design 200 of Approach-1 under a proposed scheme in accordance with the present disclosure. Referring to FIG. 2, to achieve lower coding rate, each codeword may be repeated multiple times. For instance, a LDPC parity check matrix may be kept unchanged as that defined in the IEEE 802.11n/ac/ax/be specifications. The base code rate may be R=1/2 (or another existing code rate such as ⅔, ¾ or ⅚). The number of repetitions may be any integer. Under Approach-1, there may be two options to process the codeword, namely: Option-1 and Option-2.

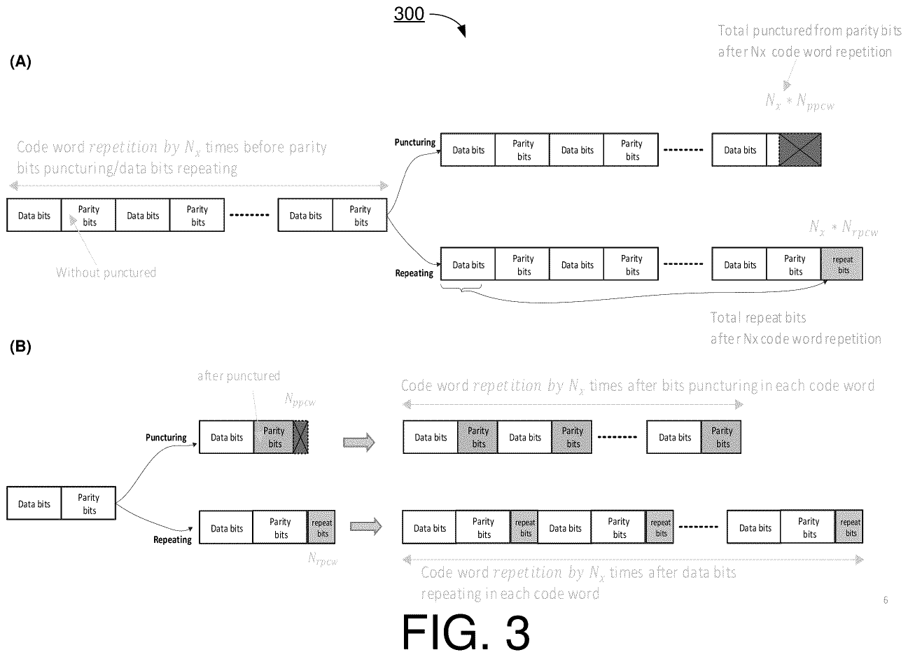

FIG. 3 illustrates an example design 300 of Option-1 and Option-2 under Approach-1 in accordance with the present disclosure. Part (A) of FIG. 3 shows Option-1 under Approach-1, and part (B) of FIG. 3 shows Optin-2 under Approach-1. In Option-1, coding may involve repetitions by Nx times followed by puncturing and repeating (of puncture). That is, a codeword generated by the LDPC encoder may be repeated by Nx times before puncturing parity bits of the codeword and repeating data bits of the codeword for a number of times. In Option-2, coding may involve puncturing and repeating (of puncture) followed by repetitions by Nx times. That is, the codeword generated by the LDPC encoder may be repeated by Nx times after puncturing parity bits of the codeword and repeating data bits of the codeword by a number of times.

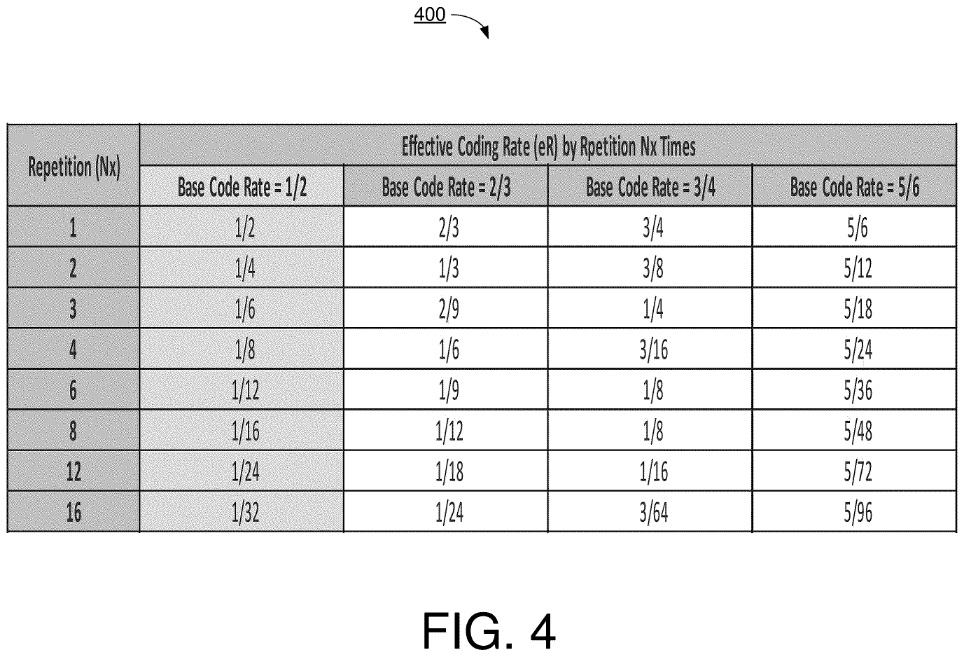

FIG. 4 illustrates an example design 400 under Approach-1 in accordance with the present disclosure. In design 400, the base code rate may be ½ or another rate, such as any of existing code rates in IEEE 802.11ax/be with R=⅔, ¾, ⅚, and so on. The number of times of repetition (Nx) may be any integer such as Nx=2, 3, 4, . . . and so on. Referring to FIG. 4, a table in design 400 shows the effective coding rate (eR) according to different base rate (e.g., ½, ⅔, ¾, ⅚) and different number of repetitions as Nx=1, 2, 3, 4, 6, 8, 12 or 16. The low coding rate (LCR) may be applied to any modulations (e.g., binary phase-shift keying (BPSK), quadrature phase-shift keying (QPSK), 16 quadrature amplitude modulation (16QAM) and the like).

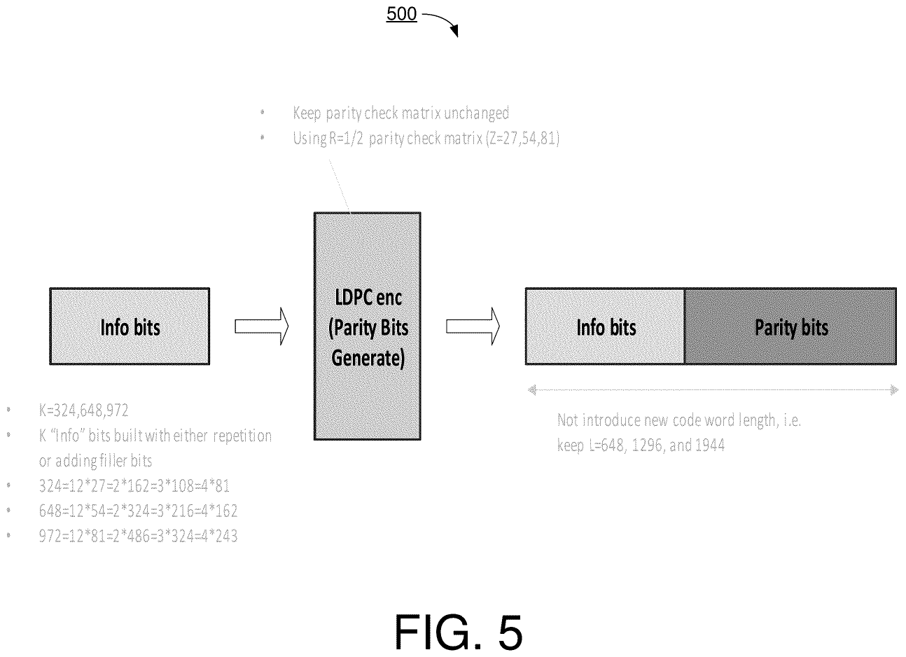

FIG. 5 illustrates an example design 500 of Approach-2 under a proposed scheme in accordance with the present disclosure. Referring to FIG. 5, the number of input bits into an encoder (e.g., LDPC encoder) at one time (k) may be k=324, 648 or 972, and the k bits may include information bits built with either repetition or filler bits. Here, 324=12*27=2*162=3*108=4*81; 648=12*54=2*324=3*216=4*162; and 972=12*81=2*486=3*324=4*243. The parity check matrix used in the LDPC encoder may be kept unchanged with R=½ parity check matrix (subblock size Z=27, 54, 81). The codeword output by the LDPC encoder may include a plurality of information bits and a plurality of parity bits, with a length L=648, 1296 or 1944. As no new codeword length is introduced, design 500 may achieve LPDC low coding rate by shortening. Under Approach-2, there may be two options to process the codeword, namely: Option-1, Option-2 and Option-3.

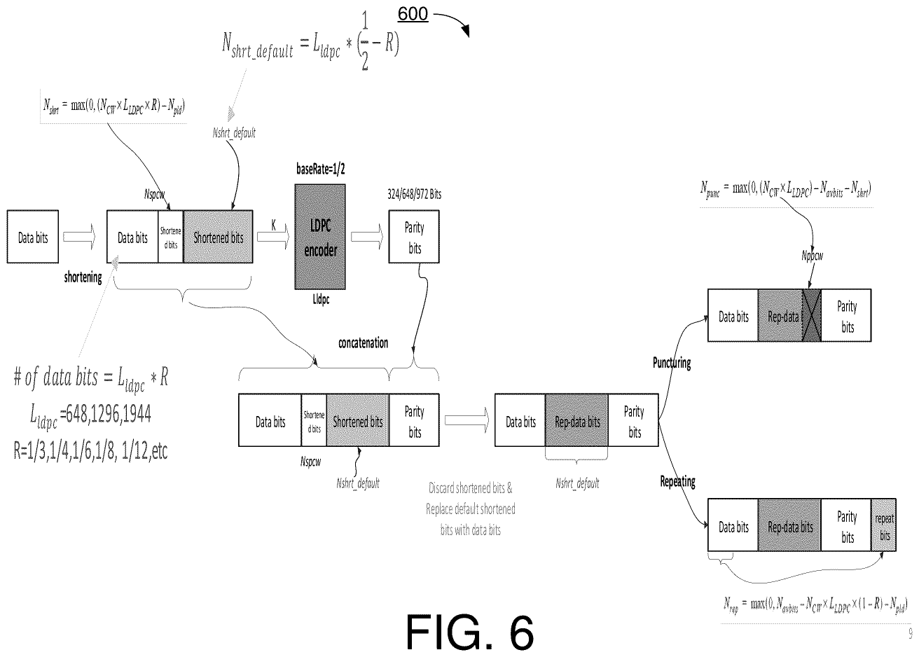

FIG. 6 illustrates an example design 600 of Option-1 under Approach-2 in accordance with the present disclosure. Specifically, FIG. 6 shows an encoding flow of LDPC low coding rate by shortening. Design 600 may achieve a low coding rate by inserting a predefined or default number of shortening bits (e.g., either all 0's or as a predefined binary sequence) as an input to the LDPC encoder. After generation of parity bits, the regular/normal shortened bits may be discarded; instead, the predefined/default shortening bits may be replaced by the data or information bits. Regarding puncturing, a number of Nppcw bits may be punctured from the “repeated data” portion instead of from parity bits. As for repeating, the same repetition may be kept as normal LDPC encoding processing. The base code rate of R=½ may be used by the LDPC encoder, and the codeword length may be maintained the same as that of a normal LDPC code.

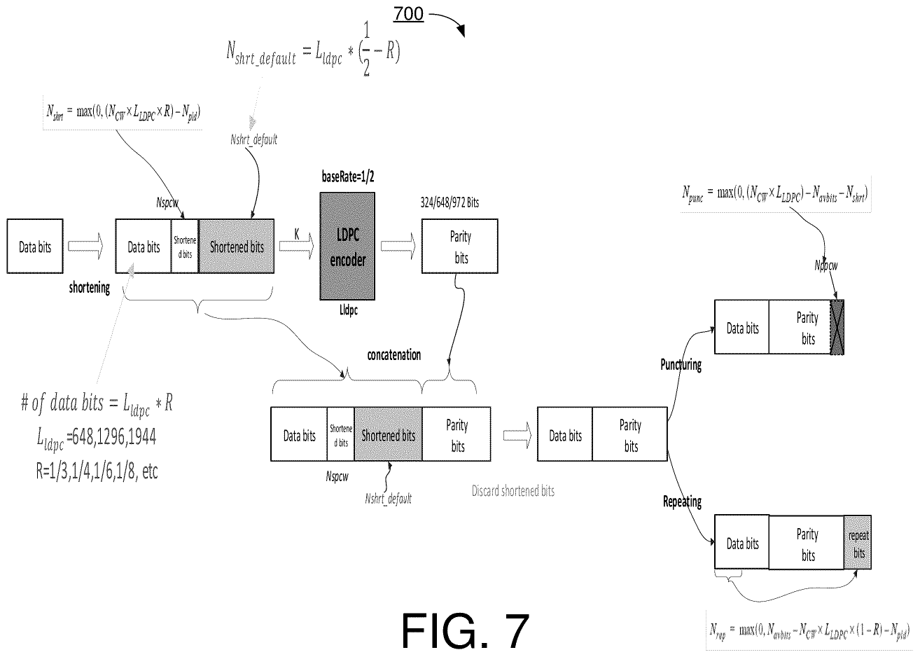

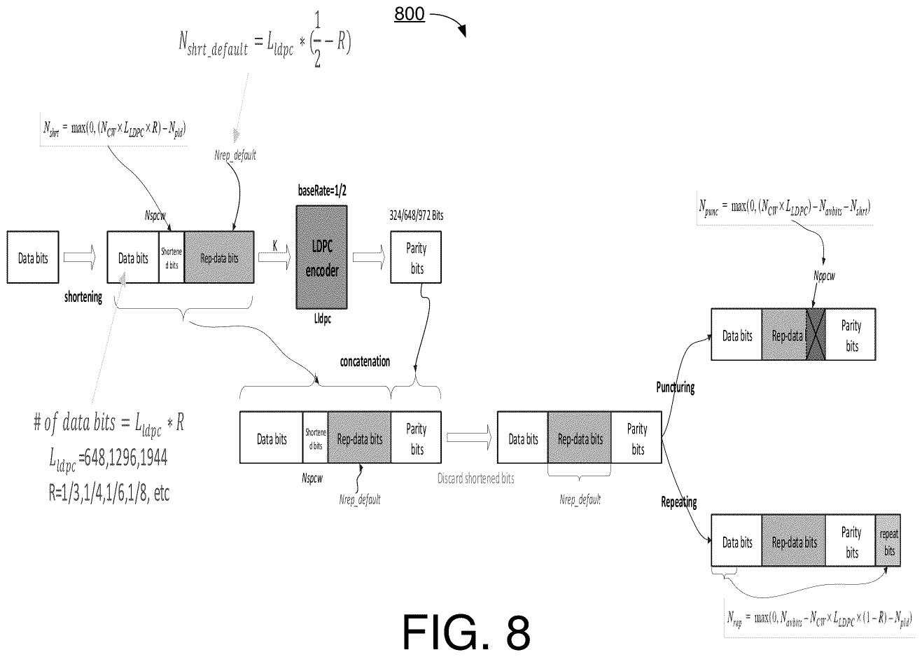

FIG. 7 illustrates an example design 700 of Option-2 under Approach-2 in accordance with the present disclosure. Specifically, FIG. 7 shows an encoding flow of LDPC low coding rate by shortening. Design 700 may achieve a low coding rate by inserting a predefined or default number of shortening bits (e.g., either all 0's or as a predefined binary sequence) as an input to the LDPC encoder. After generation of parity bits, both the regular/normal shortened bits and default shortening bits may be discarded. Regarding puncturing and repeating, the same as the normal LDPC encoding processing may be kept. The base code rate of R=½ may be used by the LDPC encoder, and the codeword length may be different from that of the regular/normal LDPC code. FIG. 8 illustrates an example design 800 of Option-3 under Approach-2 in accordance with the present disclosure. Specifically, FIG. 8 shows an encoding flow of LDPC low coding rate by shortening. Design 800 may be mostly similar to design 600 of Option-1 under Approach-2, however, instead of inserting a predefined/default number of shortening bits as the input of the LDPC encoder, the repeated data bits may be used as the shortening bits. All other processing in design 800 may be the same as that under Option-1 of Approach-2.

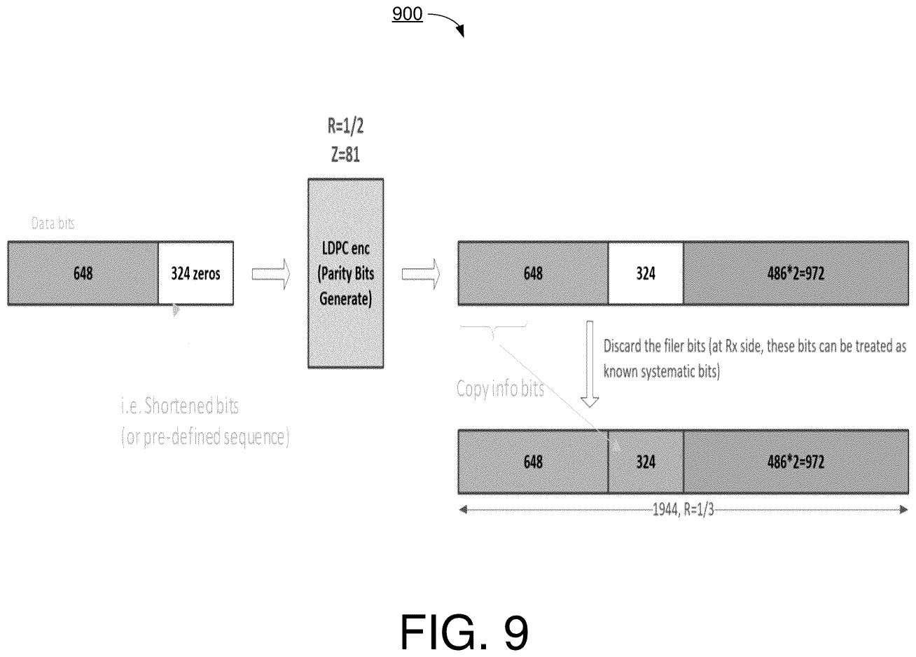

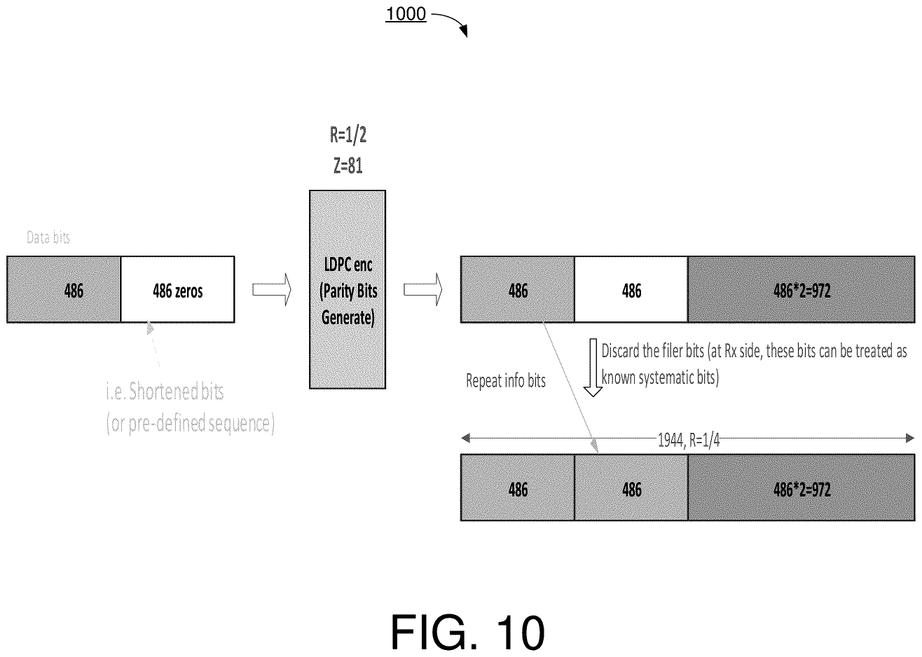

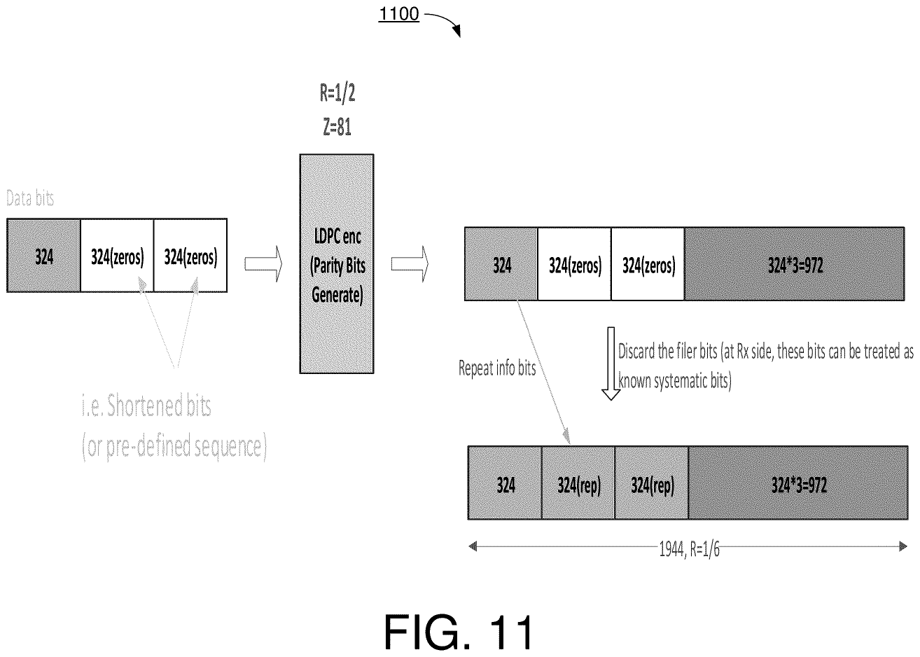

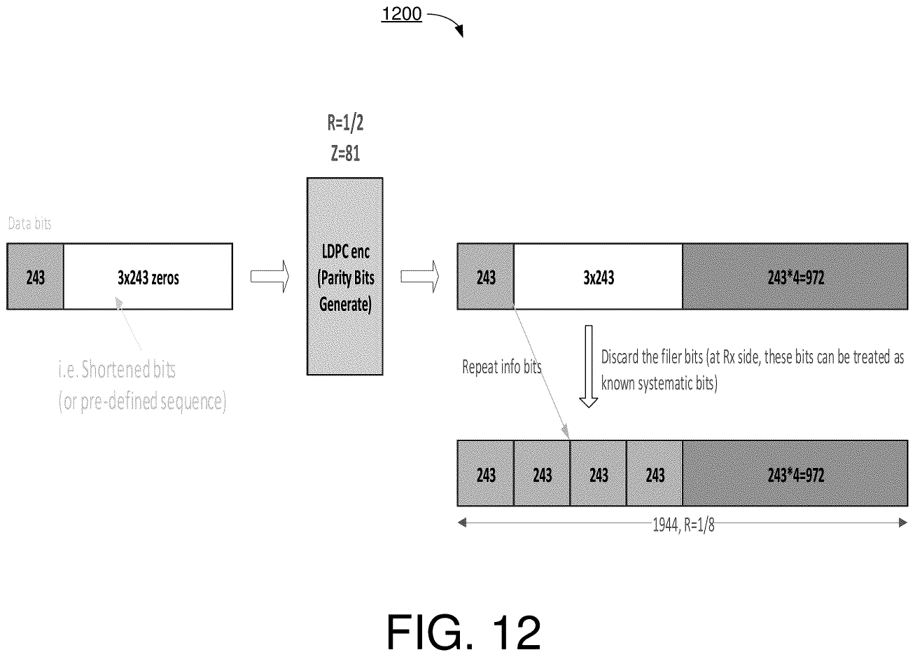

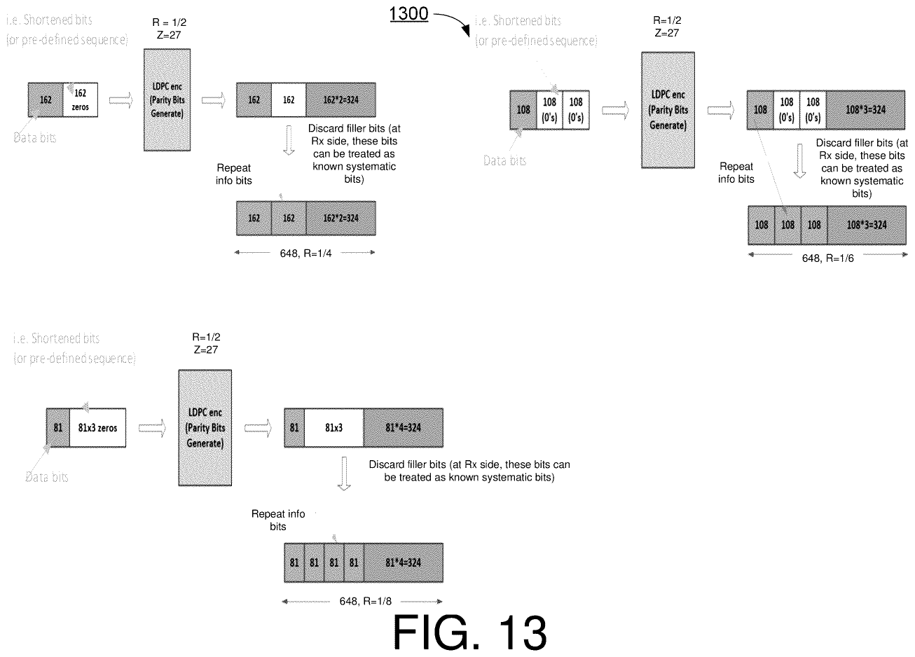

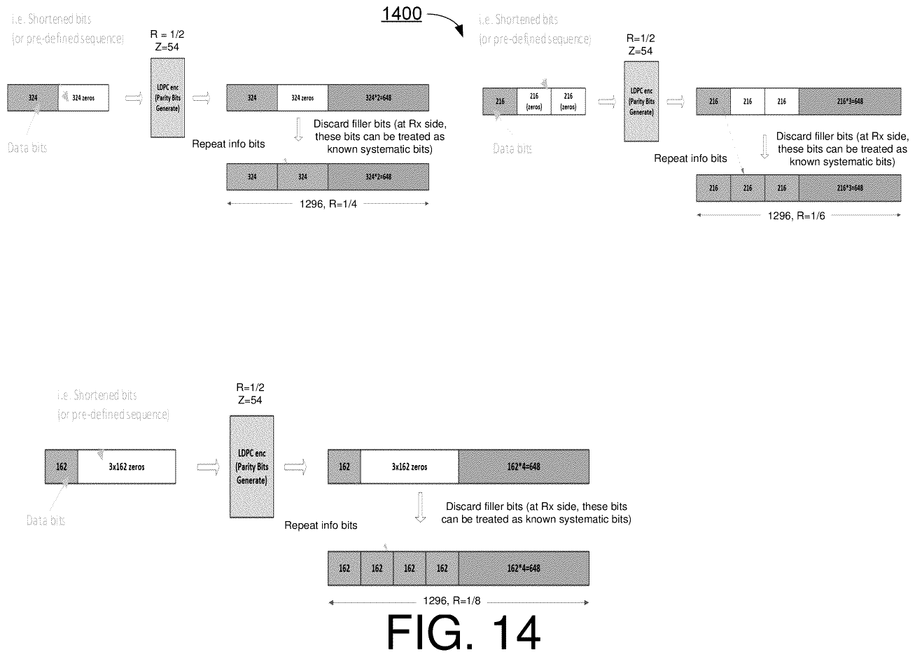

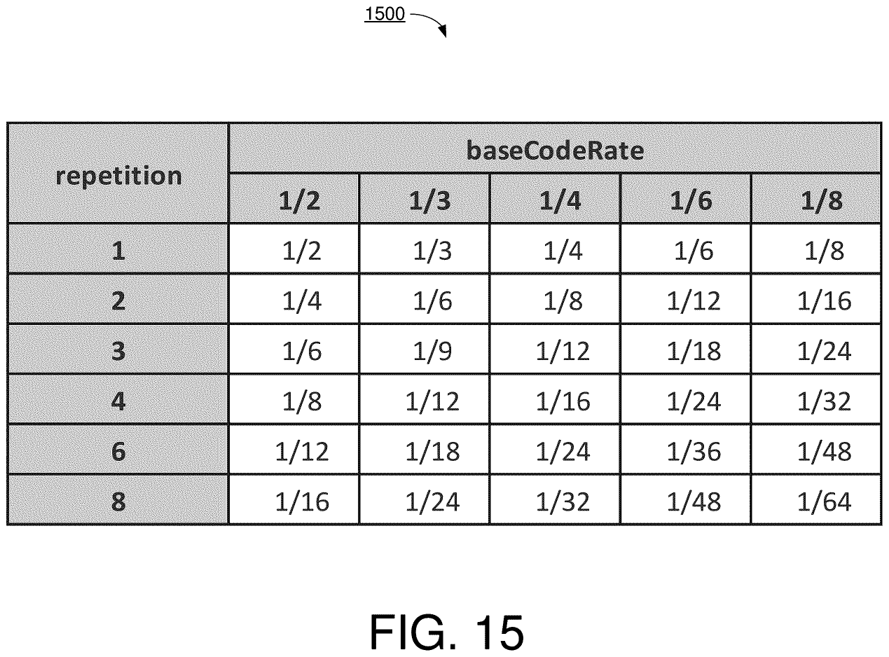

FIG. 9 illustrates an example scenario 900 of a LDPC low coding rate under Option-1 of Approach-2 in accordance with the present disclosure. In scenario 900, the outcome subblock size Z =81 and coding rate R=⅓. FIG. 10 illustrates an example scenario 1000 of a LDPC low coding rate under Option-1 of Approach-2 in accordance with the present disclosure. In scenario 900, the outcome subblock size Z=81 and coding rate R=¼. FIG. 11 illustrates an example scenario 1100 of a LDPC low coding rate under Option-1 of Approach-2 in accordance with the present disclosure. In scenario 900, the outcome subblock size Z =81 and coding rate R=⅙. FIG. 12 illustrates an example scenario 1200 of a LDPC low coding rate under Option-1 of Approach-2 in accordance with the present disclosure. In scenario 1200, the outcome subblock size Z=81 and coding rate R=⅛. FIG. 13 illustrates an example scenario 1300 of a LDPC low coding rate under Option-1 of Approach-2 in accordance with the present disclosure. In scenario 1300, the outcome subblock size Z=27 and coding rate R=½. FIG. 14 illustrates an example scenario 1400 of a LDPC low coding rate under Option-1 of Approach-2 in accordance with the present disclosure. In scenario 1400, the outcome subblock size Z=54 and coding rate R=½. FIG. 15 illustrates an example design 1500 under Approach-3 in accordance with the present disclosure. Under Approach-3, by combining Approach-1 and Approach-2, different low coding rates eR=½, ⅓, ¼, ⅙, ⅛ may be utilized as the base code rate (based on Approach-2) in addition to performing repetition (based on Approach-1) in order to achieve an even lower effective coding rate (eR) such as eR=¼, ⅙, ⅛, 1/12, 1/16, 1/24, 1/32 or any other coding rate as listed in the table in design 1500 shown in FIG. 15.

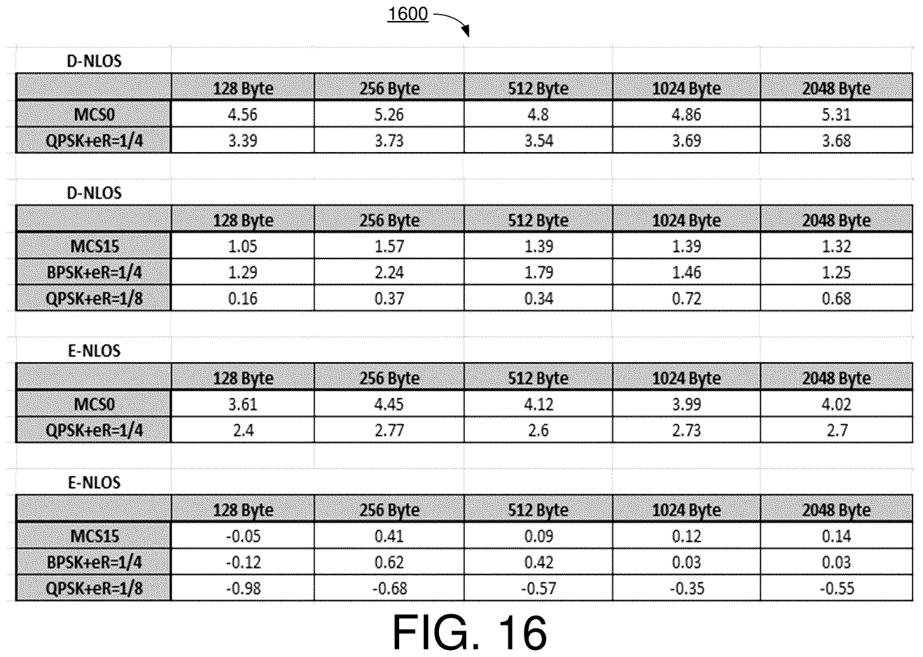

FIG. 16 illustrates an example design 1600 under a proposed scheme in accordance with the present disclosure. From various low coding rate simulations under the proposed schemes, it may be observed that, to achieve the same throughput or data rate, QPSK (which has a relatively higher modulation rate than BPSK) combined with a low coding rate tends to yield better performance than BPSK (which has a relatively lower modulation rate than QPSK) combined with R=½ or BPSK/R=½+dual carrier modulation (DCM). Parameters of the simulations include: 20 MHz bandwidth, 242-tone resource units (RUs), one spatial stream (ss), single transmission and single reception (1T1R), estimated channel condition, LDPC and no beamforming. Referring to FIG. 16, a table in design 1600 summarizes some performance comparison results for the following comparisons: (1) IEEE 802.11 be MCS 0 (BPSK+R=½) versus QPSK+R=¼; and (2) IEEE 802.11 be MCS15 (BPSK/R=½+DCM) versus QPSK+R=⅛. Accordingly, under the proposed scheme, the following options of MCS for low coding rates may be utilized to achieve robust and reliable communications: (a) a first new MCS (MCS-x) comprising QPSK+R=¼; and (b) a second new MCS (MCS-y) comprising QPSK+R=⅛.

### Illustrative Implementations

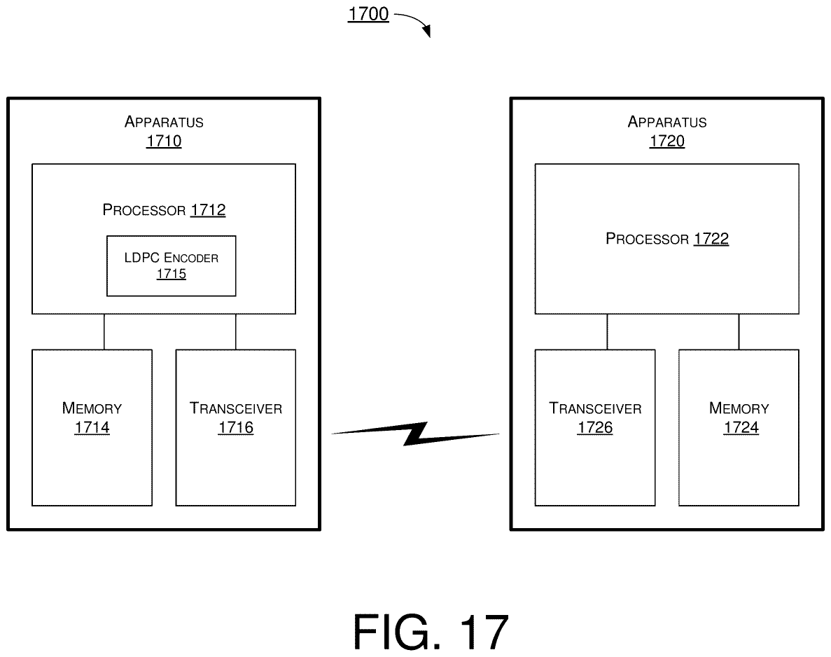

FIG. 17 illustrates an example system 1700 having at least an example apparatus 1710 and an example apparatus 1720 in accordance with an implementation of the present disclosure. Each of apparatus 1710 and apparatus 1720 may perform various functions to implement schemes, techniques, processes and methods described herein pertaining to LDPC low coding rate designs for next-generation WLANs, including the various proposed designs, concepts, schemes, systems and methods described above as well as processes described below. For instance, apparatus 1710 may be implemented in STA 110 and apparatus 1720 may be implemented in STA 120, or vice versa.

Each of apparatus 1710 and apparatus 1720 may be a part of an electronic apparatus, which may be a non-AP STA or an AP STA, such as a portable or mobile apparatus, a wearable apparatus, a wireless communication apparatus or a computing apparatus. When implemented in a STA, each of apparatus 1710 and apparatus 1720 may be implemented in a smartphone, a smart watch, a personal digital assistant, a digital camera, or a computing equipment such as a tablet computer, a laptop computer or a notebook computer. Each of apparatus 1710 and apparatus 1720 may also be a part of a machine type apparatus, which may be an IoT apparatus such as an immobile or a stationary apparatus, a home apparatus, a wire communication apparatus or a computing apparatus. For instance, each of apparatus 1710 and apparatus 1720 may be implemented in a smart thermostat, a smart fridge, a smart door lock, a wireless speaker or a home control center. When implemented in or as a network apparatus, apparatus 1710 and/or apparatus 1720 may be implemented in a network node, such as an AP in a WLAN.

In some implementations, each of apparatus 1710 and apparatus 1720 may be implemented in the form of one or more integrated-circuit (IC) chips such as, for example and without limitation, one or more single-core processors, one or more multi-core processors, one or more reduced-instruction set computing (RISC) processors, or one or more complex-instruction-set-computing (CISC) processors. In the various schemes described above, each of apparatus 1710 and apparatus 1720 may be implemented in or as a STA or an AP. Each of apparatus 1710 and apparatus 1720 may include at least some of those components shown in FIG. 17 such as a processor 1712 and a processor 1722, respectively, for example. Each of apparatus 1710 and apparatus 1720 may further include one or more other components not pertinent to the proposed scheme of the present disclosure (e.g., internal power supply, display device and/or user interface device), and, thus, such component(s) of apparatus 1710 and apparatus 1720 are neither shown in FIG. 17 nor described below in the interest of simplicity and brevity.

In one aspect, each of processor 1712 and processor 1722 may be implemented in the form of one or more single-core processors, one or more multi-core processors, one or more RISC processors or one or more CISC processors. That is, even though a singular term “a processor” is used herein to refer to processor 1712 and processor 1722, each of processor 1712 and processor 1722 may include multiple processors in some implementations and a single processor in other implementations in accordance with the present disclosure. In another aspect, each of processor 1712 and processor 1722 may be implemented in the form of hardware (and, optionally, firmware) with electronic components including, for example and without limitation, one or more transistors, one or more diodes, one or more capacitors, one or more resistors, one or more inductors, one or more memristors and/or one or more varactors that are configured and arranged to achieve specific purposes in accordance with the present disclosure. In other words, in at least some implementations, each of processor 1712 and processor 1722 is a special-purpose machine specifically designed, arranged and configured to perform specific tasks including those pertaining to LDPC low coding rate designs for next-generation WLANs in accordance with various implementations of the present disclosure.

In some implementations, apparatus 1710 may also include a transceiver 1716 coupled to processor 1712. Transceiver 1716 may include a transmitter capable of wirelessly transmitting and a receiver capable of wirelessly receiving data. In some implementations, apparatus 1720 may also include a transceiver 1726 coupled to processor 1722. Transceiver 1726 may include a transmitter capable of wirelessly transmitting and a receiver capable of wirelessly receiving data. It is noteworthy that, although transceiver 1716 and transceiver 1726 are illustrated as being external to and separate from processor 1712 and processor 1722, respectively, in some implementations, transceiver 1716 may be an integral part of processor 1712 as a system on chip (SoC), and transceiver 1726 may be an integral part of processor 1722 as a SoC.

In some implementations, apparatus 1710 may further include a memory 1714 coupled to processor 1712 and capable of being accessed by processor 1712 and storing data therein. In some implementations, apparatus 1720 may further include a memory 1724 coupled to processor 1722 and capable of being accessed by processor 1722 and storing data therein. Each of memory 1714 and memory 1724 may include a type of random-access memory (RAM) such as dynamic RAM (DRAM), static RAM (SRAM), thyristor RAM (T-RAM) and/or zero-capacitor RAM (Z-RAM). Alternatively, or additionally, each of memory 1714 and memory 1724 may include a type of read-only memory (ROM) such as mask ROM, programmable ROM (PROM), erasable programmable ROM (EPROM) and/or electrically erasable programmable ROM (EEPROM). Alternatively, or additionally, each of memory 1714 and memory 1724 may include a type of non-volatile random-access memory (NVRAM) such as flash memory, solid-state memory, ferroelectric RAM (FeRAM), magnetoresistive RAM (MRAM) and/or phase-change memory.

Each of apparatus 1710 and apparatus 1720 may be a communication entity capable of communicating with each other using various proposed schemes in accordance with the present disclosure. For illustrative purposes and without limitation, a description of capabilities of apparatus 1710, as STA 110, and apparatus 1720, as STA 120, is provided below. It is noteworthy that, although a detailed description of capabilities, functionalities and/or technical features of apparatus 1720 is provided below, the same may be applied to apparatus 1710 although a detailed description thereof is not provided solely in the interest of brevity. It is also noteworthy that, although the example implementations described below are provided in the context of WLAN, the same may be implemented in other types of networks.

Under various proposed schemes pertaining to LDPC low coding rate designs for next-generation WLANs in accordance with the present disclosure, with apparatus 1710 implemented in or as STA 110 and apparatus 1720 implemented in or as STA 120 in network environment 100, processor 1712 of apparatus 1710 may receive a plurality of input bits. Moreover, processor 1712 may code the plurality of input bits. For instance, processor 1712 may encode the input bits by a LDPC encoder 1715 of processor 1712 using a base code rate. Additionally, processor 1712 may perform either or both of a repeating operation and a shortening operation on an output of the LDPC encoder 1715 to result in an effective coding rate of coding the input bits that is lower than the base code rate.

In some implementations, the base code rate may be ½, ⅓, ¼, ⅙ or ⅛. Moreover, the effective coding rate may be ¼, ⅙, ⅛, 1/12, 1/16, 1/24 or 1/32.

In some implementations, in performing either or both of the repeating operation and the shortening operation, processor 1712 may perform the repeating operation (Approach-1, Option-1) by: (i) repeating a codeword generated by the LDPC encoder 1715 by a predefined number of times; and (ii) after repeating the codeword by the number of times: (a) puncturing parity bits of the codeword; and (b) repeating data bits of the codeword by a number of times.

In some implementations, in performing either or both of the repeating operation and the shortening operation, processor 1712 may perform the repeating operation (Approach-1, Option-2) by: (i) puncturing parity bits of a codeword generated by the LDPC encoder 1715; (ii) repeating data bits of the codeword by a number of times; and (iii) after the puncturing of the parity bits and repeating of the data bits, repeating the codeword by a predefined number of times.

In some implementations, in performing either or both of the repeating operation and the shortening operation, processor 1712 may perform the shortening operation (Approach-2, Option-1) by: (i) generating parity bits of a codeword; (ii) discarding regular shortened bits of the codeword; and (iii) replacing default shortening bits of the codeword by data or information bits. In some implementations, in performing either or both of the repeating operation and the shortening operation, processor 1712 may perform the shortening operation (Approach-2, Option-2) by: (i) generating parity bits of a codeword; and (ii) discarding both regular shortened bits and default shortening bits of the codeword.

In some implementations, in performing either or both of the repeating operation and the shortening operation, processor 1712 may perform the shortening operation (Approach-2, Option-3) by: (i) generating parity bits of a codeword; (ii) discarding regular shortened bits of the codeword; (iii) repeating data bits; and (iv) replacing default shortening bits of the codeword by the repeated data bits.

In some implementations, in performing either or both of the repeating operation and the shortening operation, processor 1712 may perform both of the repeating operation and the shortening operation (Approach-3). In such cases, the repeating operation may involve (Approach-1, Option-1): (i) repeating a codeword generated by the LDPC encoder 1715 by a predefined number of times; and (ii) after repeating the codeword by the number of times: (a) puncturing parity bits of the codeword; and (b) repeating data bits of the codeword by a number of times. Moreover, the shortening operation may involve (Approach-2, Option-1): (i) generating parity bits of a codeword; (ii) discarding regular shortened bits of the codeword; and (iii) replacing default shortening bits of the codeword by data or information bits. Alternatively, the shortening operation may involve (Approach-2, Option-2): (i) generating parity bits of a codeword; and (ii) discarding both regular shortened bits and default shortening bits of the codeword. Still alternatively, the shortening operation may involve (Approach-2, Option-3): (i) generating parity bits of a codeword; (ii) discarding regular shortened bits of the codeword; (iii) repeating data bits; and (iv) replacing default shortening bits of the codeword by the repeated data bits.

In some implementations, in performing either or both of the repeating operation and the shortening operation, processor 1712 may perform both of the repeating operation and the shortening operation (Approach-3). In such cases, the repeating operation may involve (Approach-1, Option-2): (i) puncturing parity bits of a codeword generated by the LDPC encoder 1715; (ii) repeating data bits of the codeword by a number of times; and (iii) after the puncturing of the parity bits and repeating of the data bits, repeating the codeword by a predefined number of times. Moreover, the shortening operation may involve (Approach-2, Option-1): (i) generating parity bits of a codeword; (ii) discarding regular shortened bits of the codeword; and (iii) replacing default shortening bits of the codeword by data or information bits. Alternatively, the shortening operation may involve (Approach-2, Option-2): (i) generating parity bits of a codeword; and (ii) discarding both regular shortened bits and default shortening bits of the codeword. Still alternatively, the shortening operation may involve (Approach-2, Option-3): (i) generating parity bits of a codeword; (ii) discarding regular shortened bits of the codeword; (iii) repeating data bits; and (iv) replacing default shortening bits of the codeword by the repeated data bits.

In some implementations, in coding the plurality of input bits, processor 1712 may code the plurality of input bits with a MCS of QPSK with a base code rate of ¼. Alternatively, in coding the plurality of input bits, processor 1712 may code the plurality of input bits with a MCS of QPSK with a base code rate of ⅛.

### Illustrative Processes

FIG. 18 illustrates an example process 1800 in accordance with an implementation of the present disclosure. Process 1800 may represent an aspect of implementing various proposed designs, concepts, schemes, systems and methods described above. More specifically, process 1800 may represent an aspect of the proposed concepts and schemes pertaining to LDPC low coding rate designs for next-generation WLANs in accordance with the present disclosure. Process 1800 may include one or more operations, actions, or functions as illustrated by one or more of blocks 1810 and 1820 as well as subblocks 1822 and 1824. Although illustrated as discrete blocks, various blocks of process 1800 may be divided into additional blocks, combined into fewer blocks, or eliminated, depending on the desired implementation. Moreover, the blocks/sub-blocks of process 1800 may be executed in the order shown in FIG. 18 or, alternatively in a different order. Furthermore, one or more of the blocks/sub-blocks of process 1800 may be executed repeatedly or iteratively. Process 1800 may be implemented by or in apparatus 1710 and apparatus 1720 as well as any variations thereof. Solely for illustrative purposes and without limiting the scope, process 1800 is described below in the context of apparatus 1710 implemented in or as STA 110 functioning as a non-AP STA and apparatus 1720 implemented in or as STA 120 functioning as an AP STA of a wireless network such as a WLAN in network environment 100 in accordance with one or more of IEEE 802.11 standards. Process 1800 may begin at block 1810.

At 1810, process 1800 may involve processor 1712 of apparatus 1710 receiving a plurality of input bits. Process 1800 may proceed from 1810 to 1820.

At 1820, process 1800 may involve processor 1712 coding the plurality of input bits. In coding the input bits, process 1800 may involve processor 1712 performing certain operations represented by 1822 and 1824.

At 1822, process 1800 may involve processor 1712 encoding the input bits by a LDPC encoder 1715 of processor 1712 using a base code rate. Process 1800 may proceed from 1822 to 1824.

At 1824, process 1800 may involve processor 1712 performing either or both of a repeating operation and a shortening operation on an output of the LDPC encoder 1715 to result in an effective coding rate of coding the input bits that is lower than the base code rate.

In some implementations, the base code rate may be ½, ⅓, ¼, ⅙ or ⅛. Moreover, the effective coding rate may be ¼, ⅙, ⅛, 1/12, 1/16, 1/24 or 1/32.

In some implementations, in performing either or both of the repeating operation and the shortening operation, process 1800 may involve processor 1712 performing the repeating operation (Approach-1, Option-1) by: (i) repeating a codeword generated by the LDPC encoder 1715 by a predefined number of times; and (ii) after repeating the codeword by the number of times: (a) puncturing parity bits of the codeword; and (b) repeating data bits of the codeword by a number of times.

In some implementations, in performing either or both of the repeating operation and the shortening operation, process 1800 may involve processor 1712 performing the repeating operation (Approach-1, Option-2) by: (i) puncturing parity bits of a codeword generated by the LDPC encoder 1715; (ii) repeating data bits of the codeword by a number of times; and (iii) after the puncturing of the parity bits and repeating of the data bits, repeating the codeword by a predefined number of times.

In some implementations, in performing either or both of the repeating operation and the shortening operation, process 1800 may involve processor 1712 performing the shortening operation (Approach-2, Option-1) by: (i) generating parity bits of a codeword; (ii) discarding regular shortened bits of the codeword; and (iii) replacing default shortening bits of the codeword by data or information bits.

In some implementations, in performing either or both of the repeating operation and the shortening operation, process 1800 may involve processor 1712 performing the shortening operation (Approach-2, Option-2) by: (i) generating parity bits of a codeword; and (ii) discarding both regular shortened bits and default shortening bits of the codeword.

In some implementations, in performing either or both of the repeating operation and the shortening operation, process 1800 may involve processor 1712 performing the shortening operation (Approach-2, Option-3) by: (i) generating parity bits of a codeword; (ii) discarding regular shortened bits of the codeword; (iii) repeating data bits; and (iv) replacing default shortening bits of the codeword by the repeated data bits.

In some implementations, in performing either or both of the repeating operation and the shortening operation, process 1800 may involve processor 1712 performing both of the repeating operation and the shortening operation (Approach-3). In such cases, the repeating operation may involve (Approach-1, Option-1): (i) repeating a codeword generated by the LDPC encoder 1715 by a predefined number of times; and (ii) after repeating the codeword by the number of times: (a) puncturing parity bits of the codeword; and (b) repeating data bits of the codeword by a number of times. Moreover, the shortening operation may involve (Approach-2, Option-1): (i) generating parity bits of a codeword; (ii) discarding regular shortened bits of the codeword; and (iii) replacing default shortening bits of the codeword by data or information bits. Alternatively, the shortening operation may involve (Approach-2, Option-2): (i) generating parity bits of a codeword; and (ii) discarding both regular shortened bits and default shortening bits of the codeword. Still alternatively, the shortening operation may involve (Approach-2, Option-3): (i) generating parity bits of a codeword; (ii) discarding regular shortened bits of the codeword; (iii) repeating data bits; and (iv) replacing default shortening bits of the codeword by the repeated data bits.

In some implementations, in performing either or both of the repeating operation and the shortening operation, process 1800 may involve processor 1712 performing both of the repeating operation and the shortening operation (Approach-3). In such cases, the repeating operation may involve (Approach-1, Option-2): (i) puncturing parity bits of a codeword generated by the LDPC encoder 1715; (ii) repeating data bits of the codeword by a number of times; and (iii) after the puncturing of the parity bits and repeating of the data bits, repeating the codeword by a predefined number of times. Moreover, the shortening operation may involve (Approach-2, Option-1): (i) generating parity bits of a codeword; (ii) discarding regular shortened bits of the codeword; and (iii) replacing default shortening bits of the codeword by data or information bits. Alternatively, the shortening operation may involve (Approach-2, Option-2): (i) generating parity bits of a codeword; and (ii) discarding both regular shortened bits and default shortening bits of the codeword. Still alternatively, the shortening operation may involve (Approach-2, Option-3): (i) generating parity bits of a codeword; (ii) discarding regular shortened bits of the codeword; (iii) repeating data bits; and (iv) replacing default shortening bits of the codeword by the repeated data bits In some implementations, in coding the plurality of input bits, process 1800 may involve processor 1712 coding the plurality of input bits with a MCS of QPSK with a base code rate of ¼. Alternatively, in coding the plurality of input bits, process 1800 may involve processor 1712 coding the plurality of input bits with a MCS of QPSK with a base code rate of ⅛.

### Additional Notes

The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

What is claimed is:

1. A method, comprising:
receiving, by a processor of an apparatus, a plurality of input bits; and
coding, by the processor, the plurality of input bits by performing operations comprising:
encoding the input bits by a low-density parity-check (LDPC) encoder of the processor using a base code rate; and
performing either or both of a repeating operation and a shortening operation on an output of the LDPC encoder to result in an effective coding rate of coding the input bits that is lower than the base code rate.

2. The method of claim 1, wherein the performing of either or both of the repeating operation and the shortening operation comprises performing the repeating operation by:
repeating a codeword generated by the LDPC encoder by a predefined number of times; and
after repeating the codeword by the number of times:
puncturing parity bits of the codeword; and
repeating data bits of the codeword by a number of times.

3. The method of claim 1, wherein the performing of either or both of the repeating operation and the shortening operation comprises performing the repeating operation by:
puncturing parity bits of a codeword generated by the LDPC encoder;
repeating data bits of the codeword by a number of times; and
after the puncturing of the parity bits and repeating of the data bits, repeating the codeword by a predefined number of times.

4. The method of claim 1, wherein the performing of either or both of the repeating operation and the shortening operation comprises performing the shortening operation by:
generating parity bits of a codeword;
discarding regular shortened bits of the codeword; and
replacing default shortening bits of the codeword by data or information bits.

5. The method of claim 1, wherein the performing of either or both of the repeating operation and the shortening operation comprises performing the shortening operation by:
generating parity bits of a codeword; and
discarding both regular shortened bits and default shortening bits of the codeword.

6. The method of claim 1, wherein the performing of either or both of the repeating operation and the shortening operation comprises performing the shortening operation by:
generating parity bits of a codeword;
discarding regular shortened bits of the codeword;
replacing default shortening bits of the codeword by the repeated data bits.

7. The method of claim 1, wherein the performing of either or both of the repeating operation and the shortening operation comprises performing both of the repeating operation and the shortening operation, wherein the repeating operation comprises:
repeating a codeword generated by the LDPC encoder by a predefined number of times; and
after repeating the codeword by the number of times:
puncturing parity bits of the codeword; and
repeating data bits of the codeword by a number of times.

8. The method of claim 7, wherein the shortening operation comprises:
generating parity bits of a codeword;
discarding regular shortened bits of the codeword; and
replacing default shortening bits of the codeword by data or information bits.

9. The method of claim 7, wherein the shortening operation comprises:
generating parity bits of a codeword; and
discarding both regular shortened bits and default shortening bits of the codeword.

10. The method of claim 7, wherein the shortening operation comprises:
generating parity bits of a codeword;
discarding regular shortened bits of the codeword;
repeating data bits; and
replacing default shortening bits of the codeword by the repeated data bits.

11. The method of claim 1, wherein the performing of either or both of the repeating operation and the shortening operation comprises performing both of the repeating operation and the shortening operation, wherein the repeating operation comprises:
puncturing parity bits of a codeword generated by the LDPC encoder;
repeating data bits of the codeword by a number of times; and
after the puncturing of the parity bits and repeating of the data bits, repeating the codeword by a predefined number of times.

12. The method of claim 11, wherein the shortening operation comprises:
generating parity bits of a codeword;
discarding regular shortened bits of the codeword; and
replacing default shortening bits of the codeword by data or information bits.

13. The method of claim 11, wherein the shortening operation comprises:
generating parity bits of a codeword; and
discarding both regular shortened bits and default shortening bits of the codeword.

14. The method of claim 11, wherein the shortening operation comprises:
generating parity bits of a codeword;
discarding regular shortened bits of the codeword;
repeating data bits; and
replacing default shortening bits of the codeword by the repeated data bits.

15. The method of claim 1, wherein the coding of the plurality of input bits comprises coding the plurality of input bits with a modulation and coding scheme (MCS) of quadrature phase-shift keying (QPSK) with a base code rate of ¼.

16. The method of claim 1, wherein the coding of the plurality of input bits comprises coding the plurality of input bits with a modulation and coding scheme (MCS) of quadrature phase-shift keying (QPSK) with a base code rate of ⅛.

17. An apparatus, comprising:
a transceiver configured to communicate wirelessly; and
a processor coupled to the transceiver and configured to perform operations comprising:
receiving a plurality of input bits; and
coding the plurality of input bits by performing operations comprising:
encoding the input bits by a low-density parity-check (LDPC) encoder of the processor using a base code rate; and
performing either or both of a repeating operation and a shortening operation on an output of the LDPC encoder to result in an effective coding rate of coding the input bits that is lower than the base code rate.

18. The apparatus of claim 17, wherein the base code rate comprises ½, ⅓, ¼, ⅙ or ⅛, and wherein the effective coding rate comprises ¼, ⅙, ⅛, 1/12, 1/16, 1/24 or 1/32.

19. The apparatus of claim 17, wherein the coding of the plurality of input bits comprises coding the plurality of input bits with a modulation and coding scheme (MCS) of quadrature phase-shift keying (QPSK) with a base code rate of ¼.

20. The apparatus of claim 17, wherein the coding of the plurality of input bits comprises coding the plurality of input bits with a modulation and coding scheme (MCS) of quadrature phase-shift keying (QPSK) with a base code rate of ⅛.
